(19) United States
(12) Patent Application Publication
(10) Pub. No.: US 2026/0196866 A1
(43) Pub. Date: Jul. 9, 2026

(54) MAPPING AND DISPLAYING A MAP OF INTERMITTENT FAULTS

(71) Applicant: ELECTRICAL GRID MONITORING LTD., ROSH HAAYIN (IL)

(72) Inventors: Yaakov YAHAV, NETANYA (IL); Nimrod SANDLERMAN, RAMAT GAN (IL)

(21) Appl. No.: 19/133,255

(22) PCT Filed: Dec. 6, 2023
(86) PCT No.: PCT/IB2023/062317

§ 371 Date: May 28, 2025

Related U.S. Application Data
(60) Provisional application No. 63/432,066, filed on Dec. 13, 2022.

(51) Int. Cl. H02J 13/10; G01R 31/08; G06F 3/0482; G16Y 10/35; H02J 3/38; H02J 101/24; H02J 101/28; H02J 103/30

(52) U.S. Cl. CPC H02J 13/10; G01R 31/088; G06F 3/0482; G16Y 10/35; H02J 3/381; H02J 2101/24; H02J 2101/28; H02J 2103/30

(57) ABSTRACT

A system, a method, and/or a computer program for presenting to a user a visual illustration of a selected history of short-term faults in an electric grid, the method including obtaining a collection of short-term faults in the electric grid, obtaining a list of a plurality of display conditions, receiving from the user a selection of at least one of the display conditions, and displaying on a map at least one of the short-term faults to which the selected at least one of the display conditions apply.

### FIELD

The method and apparatus disclosed herein are related to the field of electric grid, and, more particularly but not exclusively, to the management of electric distribution networks, and, more particularly but not exclusively, to locating intermittent faults in a distribution network.

### BACKGROUND

Intermittent faults are difficult to locate and repair, particularly when two or more distant effects are produced by a common fault. Intermittent faults are pervasive, and a database of intermittent faults may be huge and difficult to manage and process effectively.

The human brain is excellent in detecting visual patterns. Visual Pattern Recognition is a complex problem, so much so that the visual areas that are responsible for this process occupy up to one-half of our cortex. The groups of neurons called pattern recognizers are estimated to number 300 million. The memory area for visual stimuli is referred to as iconic memory.

It would therefore be highly advantageous to have a method and a system, devoid of the above limitations, for effectively introducing a database of intermittent faults to a human brain.

### SUMMARY

According to one exemplary embodiment there is provided a system, a method, and/or a computer program for presenting to a user a visual illustration of a selected history of short-term faults in an electric grid, the method including obtaining a collection of short-term faults in the electric grid, obtaining a list of a plurality of display conditions, receiving from the user a selection of at least one of the display conditions, and displaying on a map at least one of the short-term faults to which the selected at least one of the display conditions apply.

According to one another exemplary embodiment there is provided a map that a geographical map and/or a topology map, and further including receiving from the user a selection between the geographical map and the topology map.

According to yet another exemplary embodiment the method further includes receiving from the user a selection of a time-step value, and displaying on the map the least one of the short-term faults to which the selected at least one of the display conditions apply in an animated time-stepped manner.

According to still another exemplary embodiment the method further includes receiving from the user a selection of at least one feature of the geographical map, selecting faults that are associated with the selected at least one feature of the geographical map, and displaying the selected faults on the selected map, where the feature of the geographical map includes at least one of valley, ridge, peak, slope, height, plane, region. Further according to another exemplary embodiment the method also includes receiving from the user a selection of a of a feature of the topological map.

Yet further, according to another exemplary embodiment, the method also includes receiving from the user a selection of a weather condition, and selecting faults that are associated with the selected weather condition, where the weather condition includes at least one of: temperature, humidity, wind speed, wind direction, precipitation, rain, snow.

Still further, according to another exemplary embodiment, the method also includes applying an icon to each at least one of the short-term faults displayed on the map wherein the icon is selected according to at least one of: the display condition that applies to the short-term fault, a type of the short-term fault, and time lapsing from a previous related fault.

Unless otherwise defined, all technical and scientific terms used herein have the same meaning as commonly understood by one of ordinary skill in the relevant art. The materials, methods, and examples provided herein are illustrative only and not intended to be limiting. Except to the extent necessary or inherent in the processes themselves, no particular order to steps or stages of methods and processes described in this disclosure, including the figures, is intended or implied. In many cases the order of process steps may vary without changing the purpose or effect of the methods described.

### BRIEF DESCRIPTION OF THE DRAWINGS

Various embodiments are described herein, by way of example only, with reference to the accompanying drawings. With specific reference now to the drawings in detail, it is stressed that the particulars shown are by way of example and for purposes of illustrative discussion of the preferred embodiments only, and are presented in order to provide what is believed to be the most useful and readily understood description of the principles and conceptual aspects of the embodiment.

In this regard, no attempt is made to show structural details of the embodiments in more detail than is necessary for a fundamental understanding of the subject matter, the description taken with the drawings making apparent to those skilled in the art how the several forms and structures may be embodied in practice.

In the drawings:

FIG. 1 is a simplified illustration of a distribution grid connected to a transmission grid via a transformer station;

FIG. 2 is a simplified illustration of an example of a topological map display as provided to a user;

FIG. 3 is a simplified illustration of an example of a geographical map display as provided to a user; and

FIG. 4 is a simplified flow chart of a basic computing process executed, for example, by a grid analysis system.

### DESCRIPTION OF EMBODIMENTS

The present embodiments comprise a system, a method, and/or a computer program for a user interface effectively introducing a database of intermittent faults to a human brain. More particularly but not exclusively, the present embodiments comprise a system, a method, and/or a computer program for visual presentation of a selective cut of a database of intermittent faults. More particularly but not exclusively, the present embodiments comprise a system, a method, and/or a computer program for effective visual mapping of a selective cut of a database of intermittent faults. More particularly but not exclusively, the present embodiments comprise a system, a method, and/or a computer program for effective visual mapping of a selective cut of a database of intermittent faults in an electric grid.

The principles and operation of the system, the method, and/or the computer program for a user interface effectively introducing a database of intermittent faults to a human brain according to the several exemplary embodiments may be better understood with reference to the following drawings and accompanying description.

Before explaining at least one embodiment in detail, it is to be understood that the embodiments are not limited in its application to the details of construction and the arrangement of the components set forth in the following description or illustrated in the drawings. Other embodiments may be practiced or carried out in various ways. Also, it is to be understood that the phraseology and terminology employed herein is for the purpose of description and should not be regarded as limiting.

In this document, an element of a drawing that is not described within the scope of the drawing and is labeled with a numeral that has been described in a previous drawing has the same use and description as in the previous drawings. Similarly, an element that is identified in the text by a numeral that does not appear in the drawing described by the text, has the same use and description as in the previous drawings where it was described.

The drawings in this document are not meant to be in any scale. Different Figs. may use different scales and different scales can be used even within the same drawing. For example, different scales for different views of the same object or different scales for two adjacent objects.

The phrases “at least one” “one or more” and “and/or” are open-ended expressions that are both conjunctive and disjunctive in operation. For example, each of the expressions “at least one of A, B and C, ”at least one of A, B, or C, “one or more of A, B, and C. ”one or more of A, B, or C and “A, B, and/or C′ means A alone, B alone, C alone, A and B together, A and C together, B and C together, or A, B and C together. The terms ”a“ or ”an entity“ refers to one or more of that entity. As such, the terms ”a“ (or ”an“), ”one or more′ and “at least one’ can be used interchangeably herein.

It is also to be noted that the terms ‘comprising’, ‘including’, ‘containing’, ‘characterized by’, and ‘having’ are all inclusive, open-ended, does not exclude additional, unrecited elements or method steps, and can be used interchangeably. Particularly, these terms may imply the inclusion of a stated integer or step or group of integers or steps but not the exclusion of any other integer or step or group of integers or steps. This definition also applies to variations on the term “comprising” such as “comprise” and “comprises”.

Reference throughout this specification to “one embodiment,” “an embodiment,” or similar language means that a particular feature, structure, or characteristic that is described in connection with the embodiment is included in at least one embodiment of the present disclosure. Thus, appearances of the phrases “in one embodiment,” “in an embodiment, and similar language throughout this specification may, but do not necessarily, all refer to the same embodiment.

The term plurality, as used herein, is defined as two or more than two. The term another, as used herein, is defined as at least a second or more. The term coupled, as used herein, is defined as connected, although not necessarily directly, and not necessarily mechanically.

In this document, the term ‘computing device’ may refer to any type of computing machine, including but not limited to, a computer, a portable computer, a laptop computer, a tablet computer, a mobile communication device, a network server, a cloud computer, etc., as well as any combination thereof. Such computing device or computing machine may include any type or combination of devices, including, but not limited to, a processor or a processing device, a memory device, a storage device, a user interface device, and/or a communication device.

The terms ‘execute’, ‘perform’, compute, calculate, etc. may refer to a processor of a computational device executing a software program code embodied on a non-transitory computer readable medium to achieve a result such as described after any of the terms ‘execute’, ‘perform’, compute, calculate, etc.

The term ‘client computing device’, or ‘client device’, ‘user device’ may refer to any type of computing device that is directly used, or operated, by a user. Such device may include a user interface that may be used by a user directly, including means for user input and/or user output. Such device may be communicatively coupled to another computing devices such as a network server via a communication network.

Means for user input may include a keyboard, a pointing devices such as a mouse, a microphone, a camera, a touch-sensitive plate or display, means for user gesture control, means for haptic user control, etc.

Means for user output may include a display, and/or any other means for providing visual information, a speaker, or an earphone, and/or any other means for providing audible information, means for providing tactile and/or haptic information, etc.

The term ‘mobile communication device” may refer to devices such as a tablet, a mobile telephone, a smartphone, etc.

The term ‘network server’ or ‘server’ may refer to any type of ‘computing device’ that is communicatively coupled to a communication network and may include a cloud computer, etc.

The term ‘communication network’ or ‘network’ may refer to any type or technology for digital communication including, but not limited to, the Internet, WAN, LAN, MAN, PSDN, etc. Any of the abovementioned technologies may be wired or wireless, for example, Wireless WAN such as WiMAX, WLAN (Wi-Fi), WPAN (Bluetooth), etc. Wireless networking technology may also include PLMN, and/or any type of cellular network. The term ‘communication network’ or ‘network’ may refer to any combination of communication technologies, and to any combination of physical networks. The term ‘communication network’ or ‘network’ may refer to any number of interconnected communication networks that may be operated by one or many network operators.

The term ‘application’ may refer to a software program running on, or executed by, one or more processors of a computing devices, and particularly by a mobile computing device such as a mobile telephone, a tablet, a smartphone, etc., as well as any other mobile or portable computing facility. The term ‘mobile application’ may refer to an application executed by a mobile computing device.

In this document the terms ‘electric transmission network’, ‘electrical transmission network’, ‘electricity transmission network’, ‘electric power transmission’, ‘power line’, ‘power transmission’ and ‘power grid’ can be used interchangeably and relate to either or both underground and overhead transmission. The terms ‘grid’, or ‘electric grid’, or ‘electric network’ may refer to the electric transmission network and/or the electric distribution network, and to any part of such network between the power generating station, or stations, and the load, or the consumer(s).

The term ‘cable’, or ‘electric cable’, may refer to any single cable, or wire, or powerline, of the grid, such as a phase carrying cable. The term ‘cable device’, or ‘measuring device’, or ‘sensor’ may refer to any device mounted on an electric cable of a grid, including a sensor, a measuring device, a communication device, etc. As a non-limiting example, the cable device may derive power from the electric field and/or magnetic field around the electric cable, where the electric and/or magnetic field may be generated by the electric current flowing in the electric cable.

The term ‘measurement’ or ‘electrical measurement’ may refer to any type of measurement of any electric parameter such as voltage, current, electric field, magnetic field, resistance, capacitance, inductance, electric charge, etc. The term ‘physical measurement’ or ‘mechanical measurement’ may refer to any type of measurement of any physical parameter other than electrical parameters. Such parameters may be temperature, wind (including speed and/or direction), humidity, motion, height, (cable) depression, (cable) angle, etc. Such measurements are typically performed by a cable device mounted on an electric cable.

The system of measuring devices may measure various electric parameters in a plurality of locations in an electric cable, or an electric network, or an electric grid, and determine, by comparing a plurality of measurements, the type and location of a particular parameter, and/or phenomenon, and/or fault. Such measurement may be taken at a point of the electric cable which may be in mid cable, which is at a distance from any pole or insulator supporting the cable. In such a point, the measuring device may not have any electric contact with a reference point such as ground, or zero or neutral, or common line, etc.

In this respect, the voltage measuring device may be electrically coupled to the electric cable as a first reference point for measuring potential difference (e.g., voltage), but may lack a second electric contact to a second reference point (namely, neutral, ground, common line, etc.)

The term ‘mid cable’ may refer to any position or point along the electric cable in which the cable device, or sensor, or measuring device, may be mounted on the electric cable, and where the cable device, or sensor, or measuring device, may not have access or electric contact to a reference electric potential such as ground, zero line, common like, neutral line, etc.

The term ‘reference point’ may refer to any such reference electric potential such as ground, zero line, common like, neutral line, a powerline of a different phase, a reference plane, etc.

The term ‘electrically coupled’, or ‘electrically connected’, or simply ‘connected’ may refer to direct (e.g., galvanic contact) or indirect electric contact.

The term ‘ungrounded voltage measurement’ may refer to measuring electric voltage, or electric potential, of an electric element, such as an electric cable, being a first electric reference point, without contacting a second electric reference point, such as reference point, zero voltage line, common line, neutral line, a power line of a different phase, etc. For simplicity, all such versions of the second electric reference point may be referred herein as ‘reference point’.

The terms ‘intermittent’ or ‘instantaneous’ may refer to any electric phenomenon that is short, typically below one second. In this respect, ‘intermittent phenomenon’ may refer to any type of short-time or instantaneous change of voltage and/or current and/or power. Such ‘intermittent phenomenon’ may take the form of a surge (positive, or negative, or both), a pulse (positive, or negative, or both), a transient, a spike, etc.

The term ‘absolute time’ may refer to the time-of-day or a length of time measured from a common universal time. Absolute time may be provided via a signal from an external accurate clock such as a GPS (global positioning system) signal. The terms ‘time of flight’ or ‘time of travel’ may refer to the time it takes for a signal to travel from a first point to a second point, such as from a point of origin of the signal to a point of detection, or measurement.

The device measuring the electric signal may be an electric sensor operative to measure one or more electric parameters such as electric voltage and/or electric current. The measuring device may be mounted on the electric cable, anywhere over the electric cable, whether on or near a pole carrying the cable, or anywhere between two poles or between two insulators carrying or supporting the cable. The cable may be an overhead cable or an underground cable. For example, for an underground cable the measuring device may be placed in a location where the underground cable is exposed, and/or with no shield, such as in maintenance holes (manholes) or split points, etc.

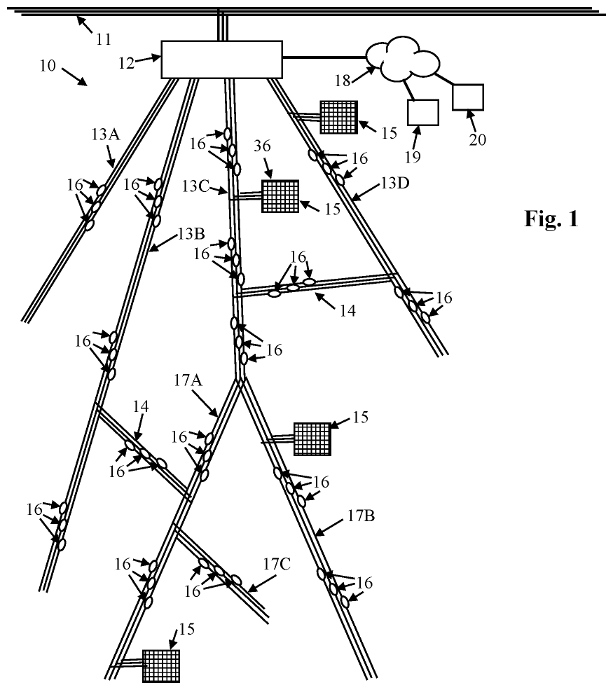

Reference is now made to FIG. 1, which is a simplified illustration of a distribution grid 10, connected to a transmission grid 11, via a transformer station 12, according to one exemplary embodiment.

As shown in FIG. 1, The distribution grid 10 may include four feed lines 13, however, any number of feed lines is contemplated. The four feed lines are enumerated as 13A, 13B, 13C, and 13D. Two tie lines 14 may be connected between feed lines 13B-13C and between 13C-13D, though any number of tie lines is contemplated.

As shown in FIG. 1, one or more photovoltaic systems 15 may be connected to any one of feed lines 13. However, any system 15 may represent any type of renewable energy electricity generating system (e.g., wind turbine, etc.). A plurality of consumer systems (not shown in FIG. 1) may be distributed along of feed lines 13. A plurality of cable devices 16 may be mounted over any of the power lines of distribution grid 10. It is appreciated that any number of cable devices 16 may be mounted over any of the power lines (phases) of distribution grid 10.

As shown in FIG. 1, feed line 13A is split into two sub-lines 17A and 17B. It is appreciated that any feed line 13A may be split into any number of sublines in various forms and split levels (e.g., 17C). The term ‘local grid’ may refer to the entire grid 10 or to a distinct part of grid 10 such as a particular feed line 13, or a sub-line 17. The entire structure and/or topology of distribution grid 10 of FIG. 1 is provided as an example only.

Communication network 18 may represent any number of communication networks of any type including wireline and wireless networks. Communication network 18 may also represent several networks that are not inter-connected, where each network serves a different pair or group of computational devices capable of communicating.

For example, communication network 18 may interconnect between transformer station 12 and grid management system 19, between grid management system 19 and grid analysis system 20, between grid analysis system 20 and energy generation systems 15, etc.

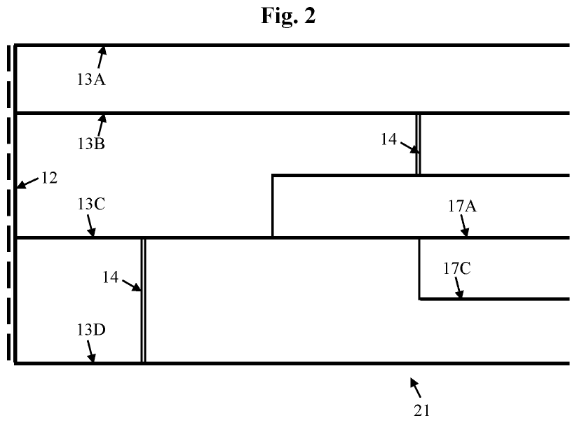

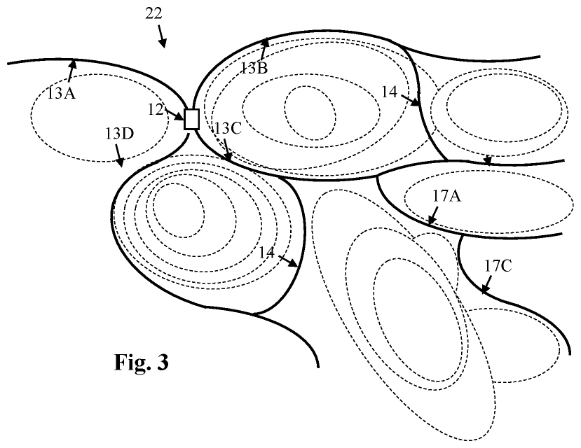

Reference is now made to FIG. 2, which is a simplified illustration of an example of a topological map display 21 as provided to a user, and to FIG. 3, which is a simplified illustration of an example of a geographical map display 22 as provided to a user, according to one exemplary embodiment.

As an option, the simplified illustrations of FIG. 2 and FIG. 3 may be viewed in the context of the details of the previous Figures. Of course, however, the simplified illustrations of FIG. 2 and FIG. 3 may be viewed in the context of any desired environment. Further, the aforementioned definitions may equally apply to the description below.

It is appreciated that the user may select to view either the topological map display or the geographical map display, or both. The two map displays may be provided on two different screens or on two parts of the same screen.

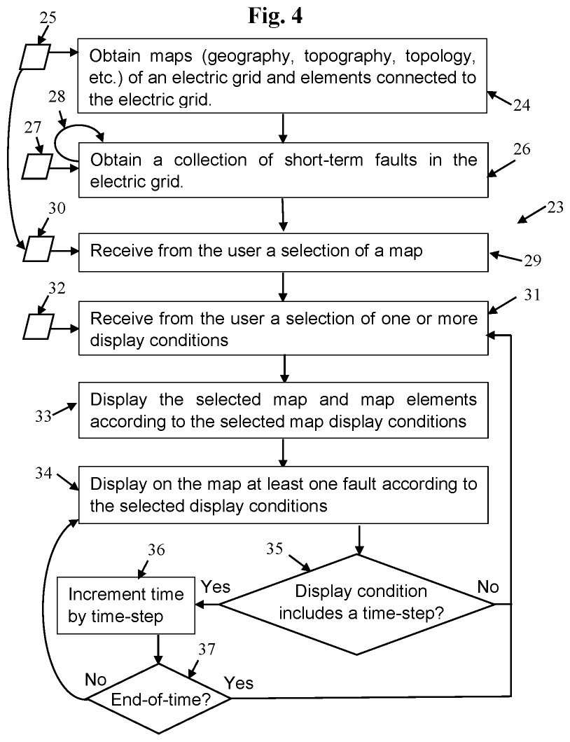

Reference is now made to FIG. 4, which is a simplified flow chart of a basic computing process 23 executed, for example, by grid analysis system 20, according to one exemplary embodiment.

As an option, the simplified flow chart of FIG. 4 may be viewed in the context of the details of the previous Figures. Of course, however, the simplified flow chart of FIG. 4 may be viewed in the context of any desired environment. Further, the aforementioned definitions may equally apply to the description below.

It is appreciated that some of the actions of basic computing process 23 may be executed by grid management system 19. It is appreciated that the flow chart of basic computing process 23 may be embodied as one or more computer programs executed by one or more processors of analysis system 20 and/or grid management system 19.

Basic computing process 23 may start with action 24 by obtaining various maps 25. Maps 25 may include a geographic map for the area of grid 10, a topographic map for the area of grid 10, a topologic map of grid 10, an electric scheme of grid 10, etc.

Basic computing process 23 may proceed to action 26 to obtain a collection of faults 27 detected in grid 10. As a non-limiting example, the collection of faults 27 may include intermittent, and/or short-time faults. The term ‘obtain’ herein may refer to actions such as ‘obtaining access to’, and/or ‘obtaining data’, and/or ‘obtaining a database of’, etc. Therefore, action 26 may be performed continuously, or repeatedly, to update the collection of faults 27 as may be indicated by curled arrow 28.

Basic computing process 23 may proceed to action 29 to receive from a user a selection of a map 30. As a non-limiting example, map selection 30 may be obtained from a user of grid management system 19.

Basic computing process 23 may proceed to action 31 to obtain a list of display conditions 32. As a non-limiting example, the list of display conditions 32 may be obtained from a user of grid management system 19. The user may create a list of display conditions 32 and/or select a list of display conditions 32, and/or update a list of display conditions 32. The display conditions 32 may include one or more map display conditions, and/or grid display conditions, and/or one or more fault display conditions, and optionally one or more time display conditions.

In this respect, map display conditions may include a type of the map to be used (e.g., geographic, topographic, topologic, schematic, etc.), the required area (e.g., area borders), types of map elements that should be included in the respective map such as roads, buildings, trees, vegetation, etc. Grid display conditions may include grid elements such as consumers, electricity providing stations, monitoring stations, etc. The term ‘electricity providing station’ may include a transformer station, an electricity generation system (e.g., a photovoltaic system 15), an electricity storage system, etc. The term ‘monitoring stations’ may include cable devices 16. Time display conditions may include start-time, end-time, fault time step, display time step, etc.

Basic computing process 23 may proceed to action 33 to display the selected map and map features and elements according to the selected map display conditions, etc., and to action 34 to display the selected faults according to the selected fault display conditions. If the display conditions include one or more time steps (action 35) the basic computing process 23 nay increment the time by the time step (action 36) and repeat action 34 with new data until end-of-time is reached (action 37). For example, during each display map step all faults occurring during the respective faults time step are displayed.

It is therefore appreciated that basic computing process 23, when executed by a processor of, for example, grid analysis system 20, may present to a user a visual illustration of a selected history of short-term faults in electric grid 10. The method, as illustrated by computing process 23, may obtain a collection of short-term faults in the electric grid, obtain a list of a plurality of display conditions, receive from the user a selection of at least one of the display conditions, and display to the user, on a map, the short-term faults to which the selected display conditions apply.

The map may be a geographical map or a topology map as selected by the user. Basic computing process 23 may also receive from the user a selection of one or more features of the geographical map. Basic computing process 23 may then select faults that are associated with the selected features, and display the selected faults on the selected map. The features of the geographical map may include one or more of valley, ridge, peak, slope, height, plane, and region. Similarly, basic computing process 23 may use a selection of features of the topological map.

The method, as illustrated by basic computing process 23, may also receive from the user a selection of a weather condition; and then select faults that are associated with the selected weather condition. Such weather conditions may include, for example, temperature, humidity, wind speed, wind direction, precipitation, rain, snow. Such weather conditions may be described by a value or a range of values.

Basic computing process 23 may also display on the relevant map an icon representing a fault. Each icon type may be associated with a different short-term fault. An icon may be selected according to the display condition that applies to the short-term fault, a type of the short-term fault; and time lapsing from a previous related fault.

Basic computing process 23 may also receive from the user a selection of a time-step value; and then display on the map the short-term faults to which the selected display conditions apply in an animated time-stepped manner.

It is appreciated that certain features, which are, for clarity, described in the context of separate embodiments, may also be provided in combination in a single embodiment. Conversely, various features, which are, for brevity, described in the context of a single embodiment, may also be provided separately or in any suitable sub-combination.

Although descriptions have been provided above in conjunction with specific embodiments thereof, it is evident that many alternatives, modifications, and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent, or patent application was specifically and individually indicated to be incorporated herein by reference. In addition, citation, or identification of any reference in this application shall not be construed as an admission that such reference is available as prior art.

What is claimed is:

1. A computer-implemented method for presenting to a user a visual illustration of a selected history of short-term faults in an electric grid, the method comprising:
obtaining a collection of short-term faults in the electric grid;
obtaining a list of a plurality of display conditions;
receiving from the user a selection of at least one of the display conditions; and
displaying on a map at least one of the short-term faults to which the selected at least one of the display conditions apply.

2. The method according to claim 1 and wherein the map is at least one of a geographical map and a topology map, and further comprising:
receiving from the user a selection between the geographical map and the topology map.

3. The method according to claim 1 and further comprising:
receiving from the user a selection of a time-step value; and
displaying on the map the least one of the short-term faults to which the selected at least one of the display conditions apply in an animated time-stepped manner.

4. The method according to claim 1 and further comprising:
receiving from the user a selection of at least one feature of the geographical map;
selecting faults that are associated with the selected at least one feature of the geographical map; and
displaying the selected faults on the selected map;
wherein the at least one feature of the geographical map comprise at least one of:
valley, ridge, peak, slope, height, plane, region.

5. The method according to claim 1 and further comprising:
receiving from the user a selection of a of a feature of the topological map

6. The method according to claim 1 and further comprising:
receiving from the user a selection of a weather condition; and
selecting faults that are associated with the selected weather condition;
wherein the weather condition comprises at least one of:
temperature, humidity, wind speed, wind direction, precipitation, rain, snow.

7. The method according to claim 1 and further comprising:
applying an icon to each at least one of the short-term faults displayed on the map wherein the icon is selected according to at least one of:
the display condition that applies to the short-term fault;
a type of the short-term fault; and
time lapsing from a previous related fault.

8. A computer program product embodied on a non-transitory computer readable medium, including instructions that, when executed by at least one processor, cause the processor to perform operations comprising:
obtaining a collection of short-term faults in the electric grid;
obtaining a list of a plurality of display conditions;
receiving from the user a selection of at least one of the display conditions; and
displaying on a map at least one of the short-term faults to which the selected at least one of the display conditions apply.

9. The computer program product according to claim 8, wherein the map is at least one of a geographical map and a topology map, and further comprising operation for:
receiving from the user a selection between the geographical map and the topology map.

10. The computer program product according to claim 8 and further comprising operations for:
receiving from the user a selection of a time-step value; and
displaying on the map the least one of the short-term faults to which the selected at least one of the display conditions apply in an animated time-stepped manner.

11. The computer program product according to claim 8 and further comprising operations for:
receiving from the user a selection of at least one feature of the geographical map;
selecting faults that are associated with the selected at least one feature of the geographical map; and
displaying the selected faults on the selected map;
wherein the at least one feature of the geographical map comprise at least one of:
valley, ridge, peak, slope, height, plane, region.

12. The computer program product according to claim 8 and further comprising operation for:
receiving from the user a selection of a of a feature of the topological map

13. The computer program product according to claim 8 and further comprising operations for:
receiving from the user a selection of a weather condition; and
selecting faults that are associated with the selected weather condition;
wherein the weather condition comprises at least one of:
temperature, humidity, wind speed, wind direction, precipitation, rain, snow.

14. The computer program product according to claim 8 and further comprising operations for:
applying an icon to each at least one of the short-term faults displayed on the map wherein the icon is selected according to at least one of:
the display condition that applies to the short-term fault;
a type of the short-term fault; and
time lapsing from a previous related fault.
